(19) United States
(12) Patent Application Publication
(10) Pub. No.: US 2012/0051133 A1
(43) Pub. Date: Mar. 1, 2012

(54) NONVOLATILE SEMICONDUCTOR STORAGE DEVICE

(75) Inventor: Kazushige KANDA, Kawasaki-Shi (JP)

(73) Assignee: KABUSHIKI KAISHA TOSHIBA, Tokyo (JP)

(21) Appl. No.: 13/214,400

(22) Filed: Aug. 22, 2011

(30) Foreign Application Priority Data
Aug. 24, 2010 (JP) 2010-187434

(51) Int. Cl. G11C 16/04

(52) U.S. Cl. 365/185.11

(57) ABSTRACT

A nonvolatile semiconductor storage device includes a memory cell array which comprises a plurality of blocks each comprising a plurality of memory cells, ordinary data being stored in ordinary blocks included in the plurality of blocks, a time code which is set for each of the ordinary blocks and which comprises time data corresponding to time when a last write operation into the ordinary block is executed being stored in a time code block included in the plurality of blocks. The time code is read out from the time code block, current time is acquired, with respect to selected one of the ordinary blocks for which a time difference between time in the time code read out and the current time becomes greater than a prescribed value, data is read and erased and the data read out is written, and a new time code corresponding to time data of the current time is written into the time code block in association with the selected ordinary block.

### CROSS-REFERENCE TO RELATED APPLICATION

This application is based upon and claims the benefit of priority from the prior Japanese Patent Application No. 2010-187434, filed on Aug. 24, 2010, the entire contents of which are incorporated herein by reference.

### BACKGROUND

1. Field

Embodiments described herein relate generally to a nonvolatile semiconductor storage device.

2. Background Art

Conventionally, a memory cell in a NAND flash memory stores two-bit data by, for example, forming four threshold voltage distributions.

Data writing into or erasing from this memory cell is implemented by injecting electrons into or extracting electrons from a floating gate of the memory cell and thereby changing a threshold voltage. Such a memory cell has a neutral threshold voltage which indicates a structurally stable state. If electrons are injected into or extracted from this memory cell, a force is exerted to restore the state of the neutral threshold voltage which is the original stable state.

For example, if the neutral threshold voltage is located near 0 V, therefore, a memory cell in an erased state having a threshold voltage lower than 0 V is subjected to force which raises the threshold voltage toward 0 V.

On the other hand, a memory cell in a write state having a threshold voltage higher than 0 V is subjected to force which lowers the threshold voltage toward 0 V.

If the threshold voltage distribution spreads in this way, then reliability of the NAND flash memory is affected.

Furthermore, as the memory cell becomes minute, dispersion control of the memory cell becomes more and more difficult and the gap between the threshold voltage distributions of the memory cell cannot be set to a large value.

In addition, requirements for endurance voltage are becoming more strict and it is necessary to lower the voltages as far as possible. For lowering the voltages, it is necessary to make the coupling ratio of the cell structure great and acquire a cell structure which is good in write and erase characteristics.

As a result, however, it becomes easy for electrons to be injected into the floating gate and extracted from the floating gate. This poses a problem that data retention characteristics of the memory cell are degraded.

### BRIEF DESCRIPTION OF THE DRAWINGS

FIG. 1 is a block diagram showing an example of the configuration of a NAND-type flash memory 100 according to the first embodiment;

FIG. 2 is a circuit diagram showing an example of the configuration according to the first embodiment that includes a memory cell array 1 shown in FIG. 1;

FIG. 3 is a cross-sectional view showing one memory cell of the memory cell array 1 shown in FIG. 2.

FIG. 4 is a cross-sectional view showing cross sections of the drain-side selection MOS transistor SGDTr, the source-side selection MOS transistor SGSTr of the memory cell array 1 shown in FIG. 2.

FIG. 5 is a diagram for explaining areas (blocks) in the memory cell array 1 shown in FIG. 1;

FIG. 6 is a block diagram showing an example of a configuration of a memory system 1000 including the NAND flash memory (NAND chip) 100 shown in FIG. 1;

FIG. 7 is a block diagram showing another example of the configuration of the memory system 1000 including the NAND flash memory (NAND chip) 100 shown in FIG. 1;

FIG. 8 is a block diagram showing still another example of the configuration of the memory system 1000 including the NAND flash memory (NAND chip) 100 shown in FIG. 1;

FIG. 9 is a block diagram showing yet another example of the configuration of the memory system 1000 including the NAND flash memory (NAND chip) 100 shown in FIG. 1.

FIG. 10 is a flow chart showing an example of a sequence at the time of writing of the NAND flash memory 100 shown in FIG. 1;

FIG. 11 is a flow chart showing an example of a sequence at the read operation of the NAND flash memory 100 shown in FIG. 1;

FIG. 12 is a flow chart showing an example of a periodic confirmation sequence of data retention characteristics in the NAND flash memory 100 shown in FIG. 1;

FIG. 13 is a diagram for explaining areas in one page of a block of the memory cell array 1 shown in FIG. 1;

FIG. 14 is a flow chart showing an example of a sequence at the write operation of the NAND flash memory 100 shown in FIG. 1;

FIG. 15 is a flow chart showing an example of a sequence at the read operation of the NAND flash memory 100 shown in FIG. 1;

FIG. 16 is a flow chart showing an example of a periodic confirmation sequence of data retention characteristics in the NAND flash memory 100 shown in FIG. 1;

FIG. 17 is a diagram for explaining areas in one block of the memory cell array 1 shown in FIG. 1;

FIG. 18 is a flow chart showing an example of a sequence at the write operation of the NAND flash memory 100 shown in FIG. 1;

FIG. 19 is a flow chart showing an example of a sequence at the read operation of the NAND flash memory 100 shown in FIG. 1; and

FIG. 20 is a flow chart showing an example of a periodic confirmation sequence of data retention characteristics in the NAND flash memory 100 shown in FIG. 1.

### DETAILED DESCRIPTION

A nonvolatile semiconductor storage device according to an embodiment, includes a memory cell array which comprises a plurality of blocks each comprising a plurality of memory cells, ordinary data being stored in ordinary blocks included in the plurality of blocks, a time code which is set for each of the ordinary blocks and which comprises time data corresponding to time when a last write operation into the ordinary block is executed being stored in a time code block included in the plurality of blocks. The time code is read out from the time code block, current time is acquired, with respect to selected one of the ordinary blocks for which a time difference between time in the time code read out and the current time becomes greater than a prescribed value, data is read and erased and the data read out is written, and a new time code corresponding to time data of the current time is written into the time code block in association with the selected ordinary block.

Hereafter, embodiments of a semiconductor storage device according to the present invention will be described more specifically with reference to the drawings. Hereafter, the case where a nonvolatile semiconductor storage device is a NAND flash memory will be described. However, the nonvolatile semiconductor storage device may be a MONOS memory or a ReRAM memory.

### First Embodiment

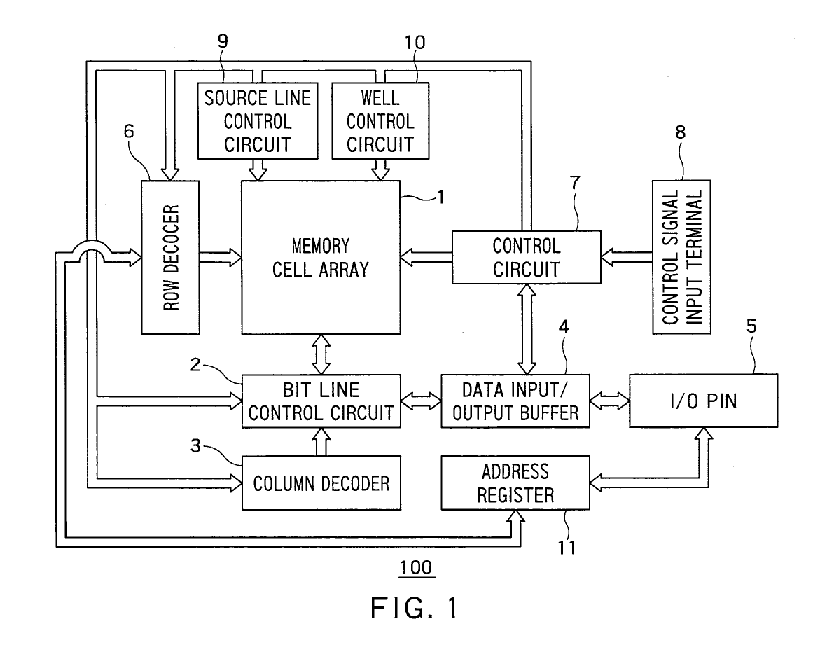

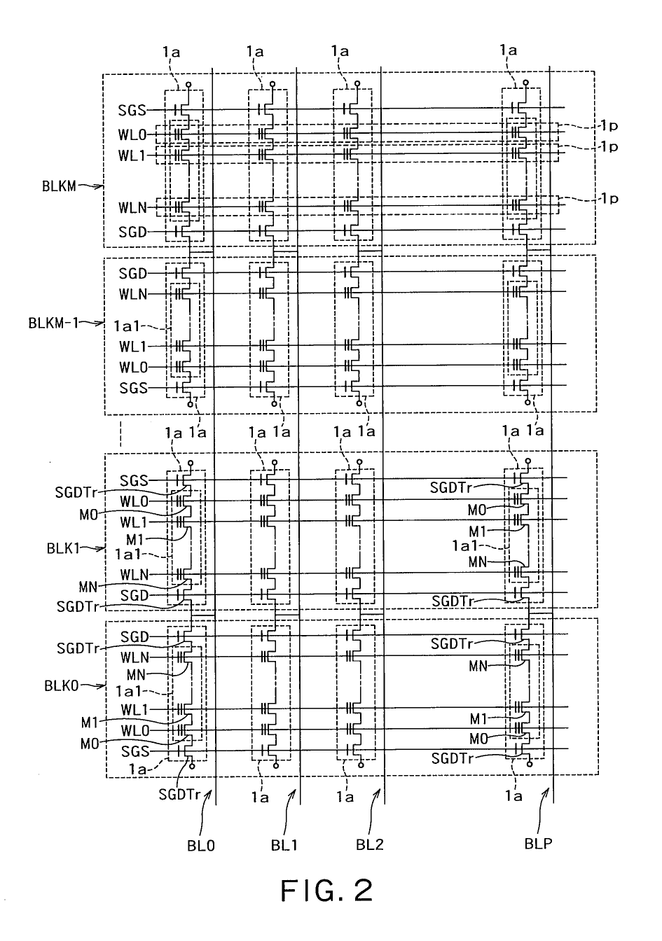

FIG. 1 is a block diagram showing an example of the configuration of a NAND-type flash memory 100 according to the first embodiment. FIG. 2 is a circuit diagram showing an example of the configuration according to the first embodiment that includes a memory cell array 1 shown in FIG. 1.

As shown in FIG. 1, the NAND-type flash memory 100 includes a memory cell array 1, a bit line control circuit 2, a column decoder 3, a data input/output buffer 4, an I/O pin 5 a row decoder 6, a control circuit 7, a control signal input terminal 8, a source line control circuit 9, a well control circuit 10, and an address register 11.

The memory cell array 1 includes a plurality of bit lines, a plurality of word lines, and a source line. This memory cell array 1 includes a plurality of blocks (FIG. 2) in which memory cells, into which data is electrically rewritable, formed from EEPROM cells are disposed in a matrix pattern.

The bit line control circuit 2 controlling the voltage of the bit lines and the row decoder 6 controlling the voltage of the word lines are connected to the memory cell array 1. In a write operation of data, one of the blocks is selected by the row decoder 6, and the other blocks are not selected.

This bit line control circuit 2 reads data of a memory cell of the memory cell array 1 through the bit line, detects the status of the memory cell through the bit line, or writes data into the memory cell by applying a write control voltage to the memory cell through the bit line.

In addition, the bit line control circuit 2, the column decoder 3 and the data input/output buffer 4 are connected. The data storage circuit disposed inside the bit line control circuit 2 is selected by the column decoder 3, and the data of the memory cell that is read out by the data storage circuit is output to the outside thereof (controller described bilow) from the I/O pin 5 through the data input/output buffer 4.

In addition, write data input from the outside to the I/O pin 5 is stored in the data storage circuit that is selected by the column decoder 3 through the data input/output buffer 4. From the I/O pin 5, various commands such as a write, a read, an erase, and a status read and an address other than the write data are also input.

The row decoder 6 is connected to the memory cell array 1. The row decoder 6 selects a block in the memory cell array 1 in accordance with an address signal which is input from external via the I/O pin 5 and the address register 11 to select a block. And the row decoder 6 applies a voltage required for reading, writing or erasing supplied from the control circuit 7, to a word line of a selected block. Note that for example, at the time of test operation, the address signal is input from an external tester (not shown).

In other words, the row decoder 6 is adapted to select one of a plurality of blocks in the memory cell array 1 described later in accordance with an address signal and control the voltage on the word line.

The source line control circuit 9 is connected to the memory cell array 1. This source line control circuit 9 is configured so as to control the voltage of the source line SRC.

The well control circuit 10 is connected to the memory cell array 1. This well control circuit 10 is configured so as to control the voltage of a well in which the memory cells are formed.

The control circuit 7 is configured so as to control the memory cell array (the block) 1, the bit line control circuit 2, the column decoder 3, the data input/output buffer 4, the row decoder 6, the source line control circuit 9, and the well control circuit 10. That is, the control circuit 7 has a function of generally controlling the overall operation of the NAND-type flash memory 100.

Here, a voltage booster circuit (not shown) that raises the voltage of a power source voltage is assumed to be included in the control circuit 7. The control circuit 7 is configured so as to raise the voltage of the power source voltage as necessary by using the voltage booster circuit and supply this voltage to the bit line control circuit 2, the column decoder 3, the data input/output buffer 4, the row decoder 6, the source line control circuit 9, and the well control circuit 10.

This control circuit 7 controls operation according to control signals (a command latch enable signal CLE, an address latch enable signal ALE, a ready/busy signal RY/BY, or the like) that are input from the outside (the controller) through the control signal input terminal 8 and a command that is input from the I/O pin 5 through the data input/output buffer 4. In other words, when data is written, verified, read, and erased according to the control signals and the command, the control circuit 7 generates a desired voltage and supplies this voltage to each portion of the memory cell array 1.

As shown in FIG. 2, the memory cell array 1 includes blocks BLK0 to BLKM (which are hereafter referred to simply as BLK for convenience in some cases) formed by connecting a plurality of NAND cell units 1a. The blocks BLK0 to BLKM become units in data writing and erasing.

Each NAND cell unit 1a is formed of a plurality of (n+1 (for example, sixty-four) memory cells M0 to MN connected in series to constitute a string, a drain side selection MOS transistor SGDTr, and a source side selection MOS transistor SGSTr. Furthermore, the source side selection MOS transistor SGSTr is connected to a source line SRC (not shown). At this point, the source side selection MOS transistor SGSTr and the drain side selection MOS transistor SGDTr are nMOS transistors.

Control gates of the memory cells M0 to MN disposed in each row are connected to word lines WL0 to WLN, respectively. In other words, a plurality of word lines WL0 to WLN are connected to the control gates of the memory cells M0 to MN over a plurality of strings. Note that each page 1p is formed of a plurality of memory cells connected to each of the word lines WL0 to WLN.

Bit lines BL0 to BLn are disposed to be perpendicular to the word lines WL0 to WLN.

Furthermore, the drain side selection MOS transistor SGDTr is connected at its gate to a drain side selection gate line SGD. And the drain side selection gate transistor SGDTr is connected between a first end of a string 1a1 and one of the bit lines BL0 to BLP.

Furthermore, the source side selection MOS transistor SGSTr is connected at its gate to a source side selection gate line SGS. And the source side selection gate transistor SGSTr is connected between a second end of the string 1a1 and the source line SRC.

In other words, the row decoder 6 conducts selection on the blocks BLK0 to BLKM in the memory cell array 1 in accordance with the address which is input, and controls a write/read operation of the selected block. In other words, the row decoder 6 selects a memory cell by controlling voltages applied to the drain side selection gate line and the source side selection gate line and controlling voltages applied to the word lines (the control gates of the memory cells) in accordance with the address which is input.

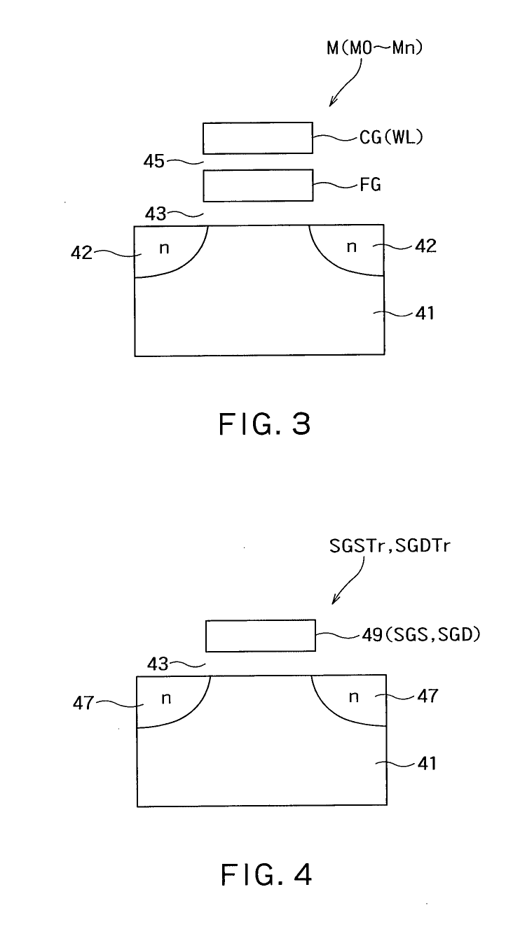

Here, FIG. 3 is a cross-sectional view showing one memory cell of the memory cell array 1 shown in FIG. 2.

As shown in FIG. 3, the memory cell M (M0 to Mn) has a floating gate FG, a control gate CG, and a diffusion layer 42. The control gate CG is electrically connected to the word line WL and is common to the plurality of the memory cells M (FIG. 2).

In a well (here, a p well) 41 formed in the semiconductor substrate, a diffusion layer 42 that becomes a source-drain diffusion layer (here, an n+ diffusion layer) of the memory cell M is formed. In addition, a floating gate FG is formed on the well 41 with a gate insulating film (tunnel insulating layer) 43 interposed therebetween. A control gate CG is formed on the floating gate FG with a gate insulating film 45 interposed therebetween.

This memory cell M is configured such that data is stored therein according to a threshold voltage and the stored data can be electrically rewritten by controlling the threshold voltage. The threshold voltage is determined based on the amount of electric charges that can be accumulated in the floating gate FG. The amount of electric charges accumulated in the floating gate FG can be changed according to a tunnel current passing through a gate insulating film 43.

In other words, when the control gate CG is maintained at a voltage that is sufficiently high with respect to the well 41 and the diffusion layer (the source diffusion layer/the drain diffusion layer) 42, electrons are injected into the floating gate FG through the gate insulating film 43. Accordingly, the threshold voltage of the memory cell M becomes higher (for example, it corresponds to a write state when the stored data is binary).

On the other hand, when the well 41 and the diffusion layer (the source diffusion layer/the drain diffusion layer) 42 are maintained at a voltage that is sufficiently high with respect to the control gate CG, electrons are extracted from the floating gate FG through the gate insulating film 43. Accordingly, the threshold voltage of the memory cell M becomes lower (for example, it corresponds to an erase state when the stored data is binary).

As described above, the memory cell M can rewrite the stored data by controlling the amount of electric charges accumulated in the floating gate FG.

FIG. 4 is a cross-sectional view showing cross sections of the drain-side selection MOS transistor SGDTr, the source-side selection MOS transistor SGSTr of the memory cell array 1 shown in FIG. 2.

As shown in FIG. 4, in the well 41, a diffusion layer 47 that becomes a source diffusion layer/drain diffusion layer of the drain-side selection MOS transistor SGDTr and the source-side selection MOS transistor SGSTr is formed. On the well 41, a control gate 49 (SGS and SGD) is formed on the well 41 with a gate insulating film (tunnel insulating layer) 43 interposed therebetween.

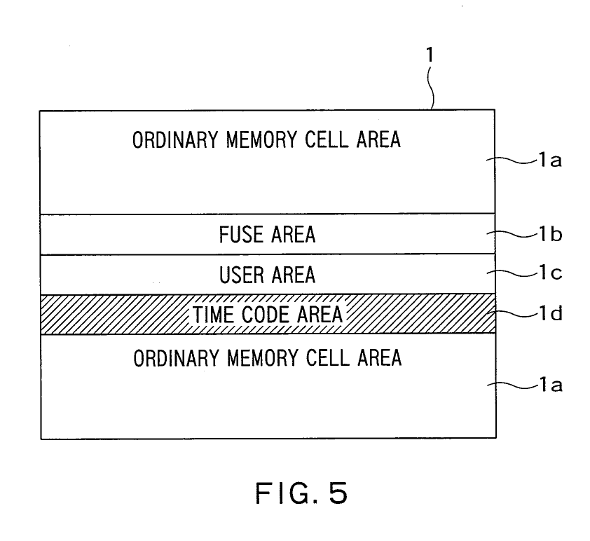

FIG. 5 is a diagram for explaining areas (blocks) in the memory cell array 1 shown in FIG. 1.

As shown in FIG. 5, the memory cell array 1 includes an ordinary memory cell area (ordinary block) 1a for storing ordinary data, a fuse area (block) 1b for storing defective addresses and adjustment values specific to the chip in voltage trimming or the like, a user area (block) 1c for storing a basic program of a controller in a card or memory module, and a time code area (time code block) 1d for storing a time code required for time management. Note that each area is formed of one or a plurality of blocks.

Note that in the time code area 1d, for example, the time code is stored by using a binary value or the time code is stored by using complementary data. As a result, reliability of data stored in the time code area 1d is made high. Note that the time code is set for every ordinary block, and time data corresponding to time when a last write operation of the corresponding block is executed is included in the time code.

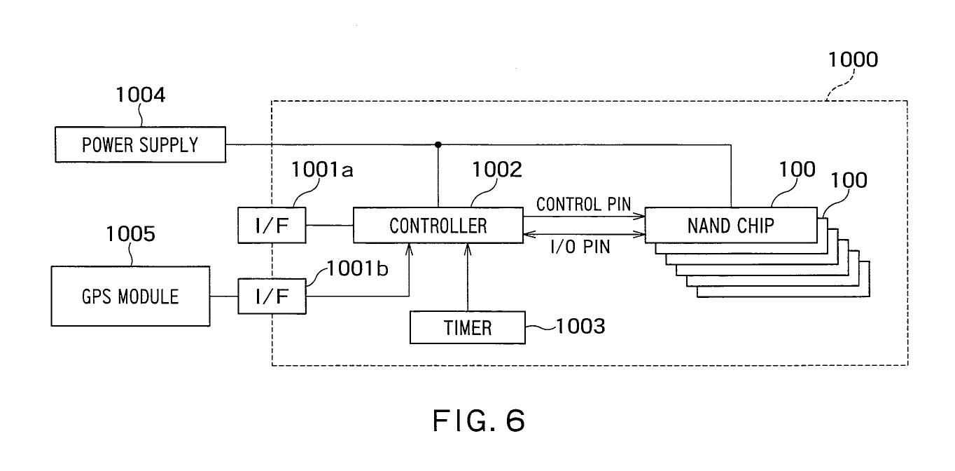

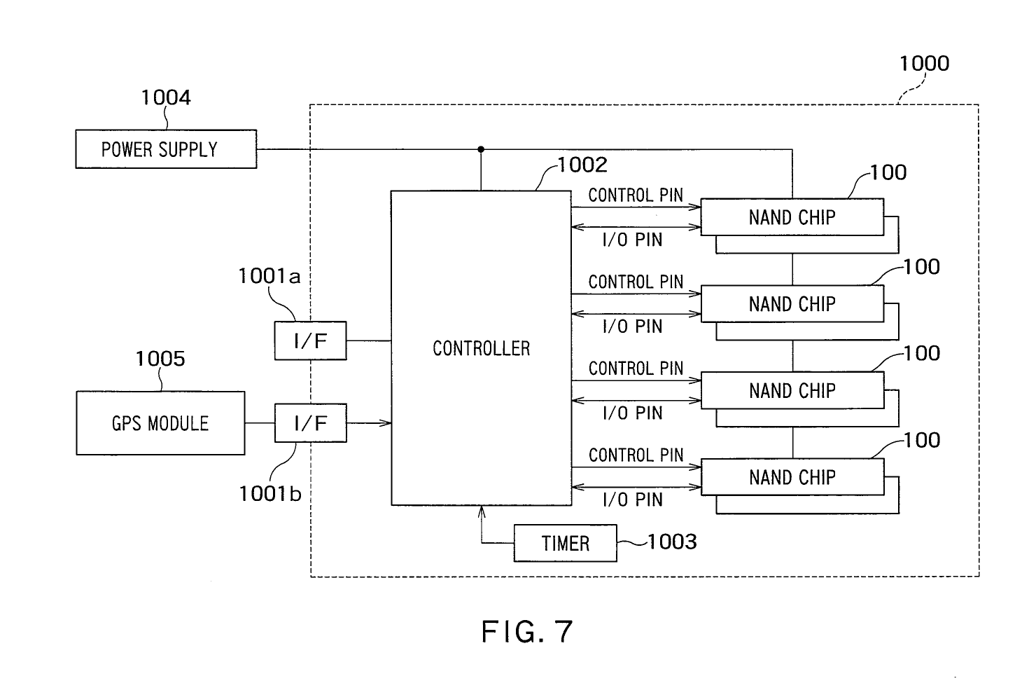

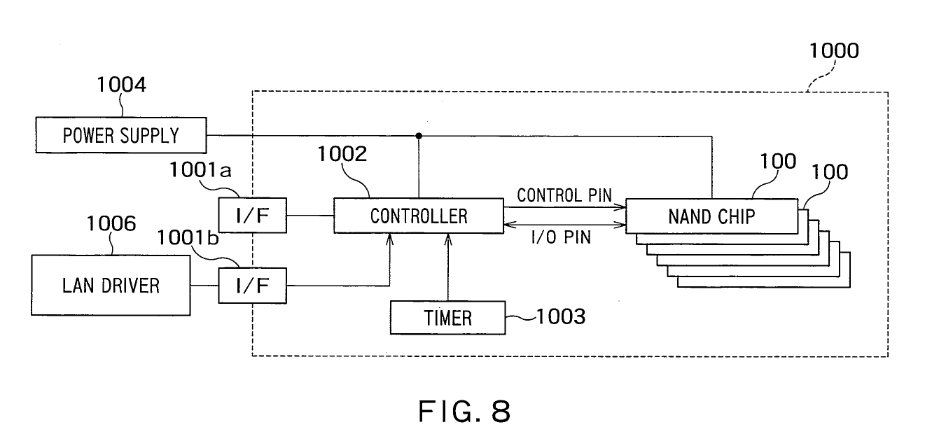

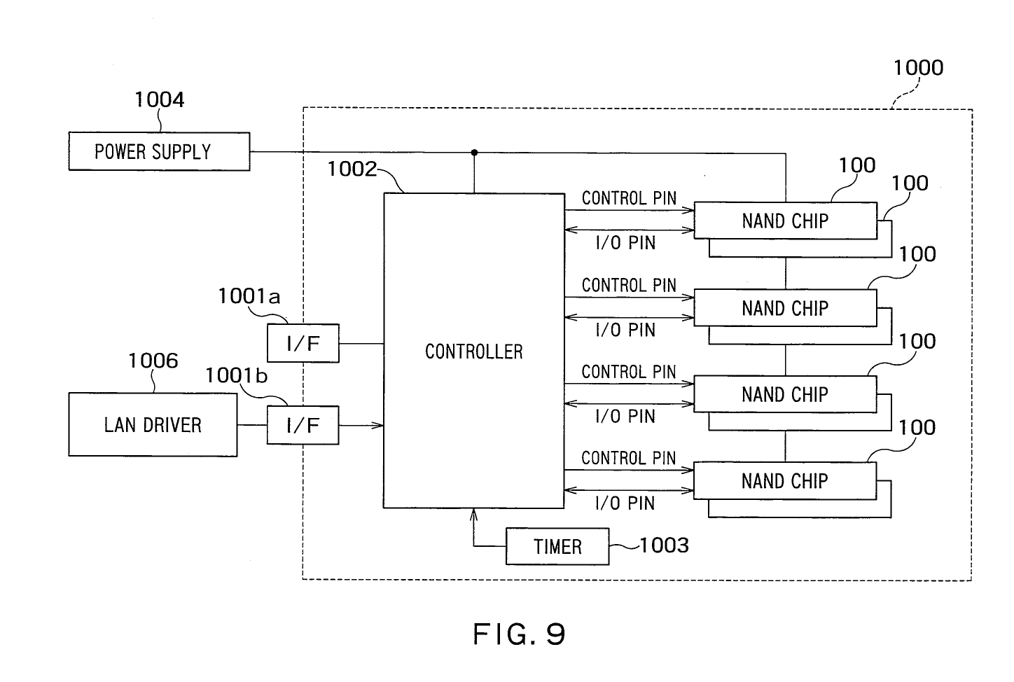

FIG. 6 is a block diagram showing an example of a configuration of a memory system 1000 including the NAND flash memory (NAND chip) 100 shown in FIG. 1. FIG. 7 is a block diagram showing another example of the configuration of the memory system 1000 including the NAND flash memory (NAND chip) 100 shown in FIG. 1. FIG. 8 is a block diagram showing still another example of the configuration of the memory system 1000 including the NAND flash memory (NAND chip) 100 shown in FIG. 1. FIG. 9 is a block diagram showing yet another example of the configuration of the memory system 1000 including the NAND flash memory (NAND chip) 100 shown in FIG. 1.

In FIGS. 6 to 9, a NAND flash memory is represented as a NAND chip. Furthermore, in FIGS. 6 to 9, the same reference numeral denotes the same configuration.

As shown in FIG. 6, the memory system 1000 includes a plurality of interfaces 1001a and 1001b, a controller 1002, a timer 1003, and a plurality of NAND flash memories (NAND chips) 100.

As already described, the controller 1002 transmits and receives data and the like to and from the NAND chips 100 via the I/O pin. Furthermore, the controller 1002 transmits a control signal to the NAND flash memories 100 via the control pin 8 to control the operation mode of the NAND flash memories 100. Furthermore, the controller 1002 conducts driving in accordance with a signal which is input from the interface 1001a.

A power supply 1004 is adapted to supply power to the controller 1002 and the NAND chips 100. The power supply 1004 is an external power supply, a battery, or the like which can supply predetermined power.

Note that the controller 1002 has a function of monitoring a voltage of the power supply 1004 and responding to its drop to below a prescribed value by notifying the external to that effect. If the voltage of the power supply 1004 is kept at a predetermined value as a result, then it is possible to prevent the falling of the voltage supplied by the power supply 1004 from stopping the drive of the controller 1002.

A Global Positioning System (GPS) module 1005 which is a time supply device is adapted to supply time information such as current information to the controller 1002 via the interface 1001b. In other words, the controller 1002 is adapted to be able to acquire the current time on the basis of time information supplied from the GPS module 1005.

The timer 1003 is adapted to count the time and supply the count value to the controller 1002. As a result, the controller 1002 is adapted to, for example, be able to acquire the time elapsed from certain time such as time when a command is input. Note that the controller 1002 may be adapted to correct time obtained from the count value which is input from the timer 1003 on the basis of, for example, the time information supplied from the GPS module 1005.

In the configuration of the memory system 1000 shown in FIG. 6, transmission/reception of data or the like to/from one of the plurality of NAND flash memories 100 is conducted via the control pin and the I/O pin.

In the configuration of the memory system 1000 shown in FIG. 7, transmission/reception of data or the like to/from four out of the plurality of NAND flash memories 100 is conducted in parallel via four control pins and four I/O pins.

In the configurations of the memory system 1000 shown in FIGS. 8 and 9, a local area network (LAN) driver 1006 which is a time supply device is adapted to supply time information such as current time to the controller 1002 via the interface 1001b, instead of the GPS module 1005 shown in FIGS. 6 and 7. In other words, the controller 1002 is adapted to acquire the current time on the basis of time information supplied from the LAN driver 1006.

In the configuration of the memory system 1000 shown in FIG. 8, transmission/reception of data or the like to/from one of the plurality of NAND flash memories 100 is conducted via the control pin and the I/O pin.

In the configuration of the memory system 1000 shown in FIG. 9, transmission/reception of data or the like to/from four out of the plurality of NAND flash memories 100 is conducted in parallel via four control pins and four I/O pins.

An example of operation for improving data retention characteristics of the NAND flash memory 100 having the configuration described heretofore will now be described.

For example, when the power supply is not constantly on, a sequence for improving the data retention characteristics at predetermined time cannot be executed. In the present embodiment, therefore, an example in which the sequence is executed when read, write and erase operation is conducted when the power supply is on will be described.

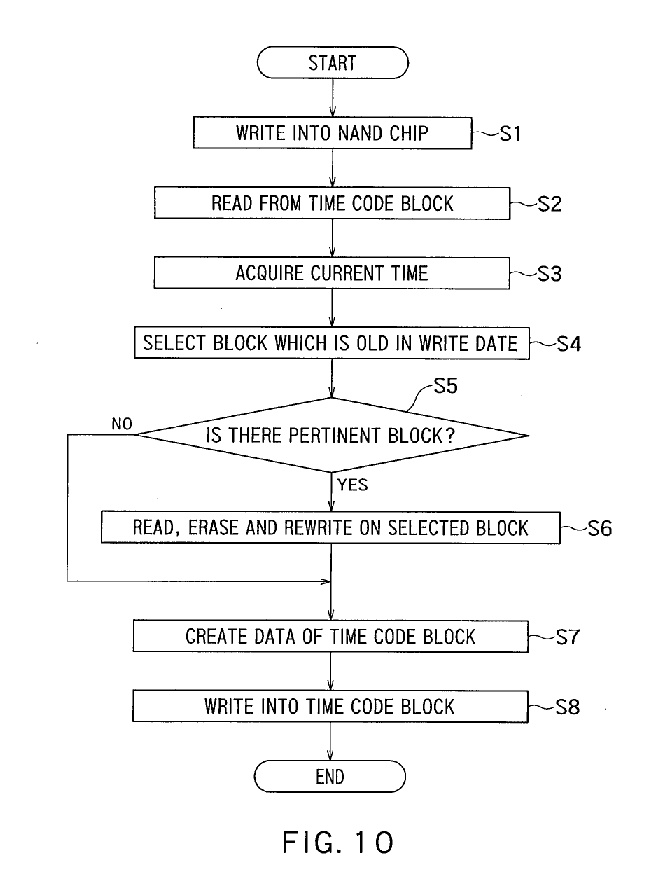

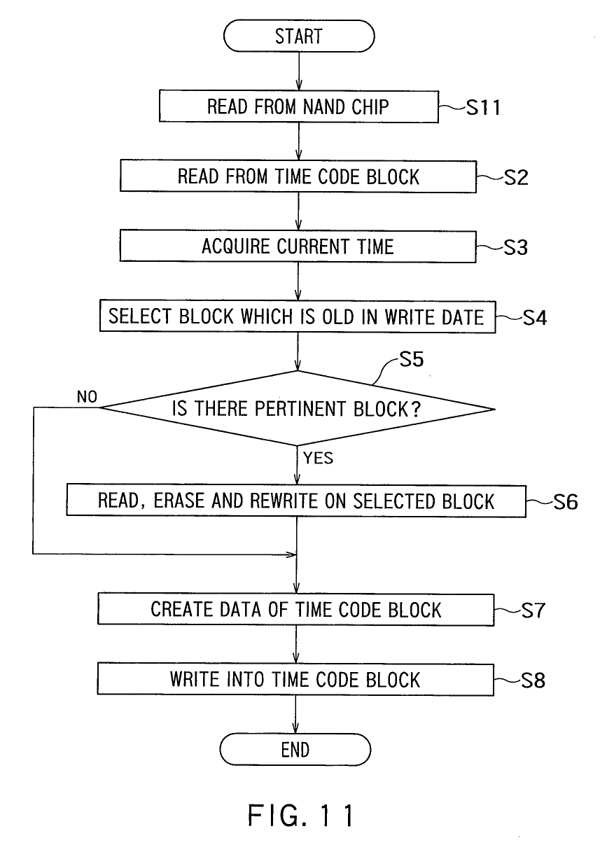

Normally, the erase operation is executed in a set with the write operation. A sequence at the time of writing and a sequence at the time of reading are shown in FIGS. 10 and 11, respectively.

FIG. 10 is a flow chart showing an example of a sequence at the time of writing of the NAND flash memory 100 shown in FIG. 1.

As shown in FIG. 10, in response to a command or the like which is input from the controller 1002, the NAND flash memory 100 first executes write operation into a selected block of a writing object included in an ordinary memory area (ordinary block) is of the memory cell array 1 (step S1).

Note that when the write operation is executed, data erasing of every selected block is executed before data writing. If the selected block has no data written therein, however, erasing is not executed.

Then, the NAND flash memory 100 reads out a time code of every block stored in the time code area (time code block) 1d (step S2). In this time code, time data concerning time when a last write operation has been executed in a block corresponding to the time code is included.

In this way, the NAND flash memory 100 writes data into a block of a writing object selected from ordinary blocks included in a plurality of blocks, and then reads out a time code from the time code block.

Then, the controller 1002 acquires current time on the basis of time information supplied from a time supply device such as the GPS module 1005 (step S3).

Then, the controller 1002 compares time in time data of a block in each time code which is read out with the current time, and selects a block having a time difference greater than a prescribed value (satisfying a prescribed condition). In other words, the controller 1002 selects blocks subjected to execution of a last write operation over a certain first prescribed period before, out of all blocks (step S4). Note that a restriction may be provided on the number of selected blocks.

Then, the processing proceeds to step S5. Upon judging that a block corresponding to the above-described condition exists, the controller 1002 executes a read operation, an erase operation, and a write operation (rewrite operation) on the selected block (step S6).

In other words, the controller 1002 reads data from, erases the data from and writes the data which is read into, selected ordinary blocks for which a time difference between time in a time code which is read out and the current time becomes greater than a prescribed value.

Note that data rewritten into the selected block is the same as data stored in the selected block before rewriting.

As a result, rewrite operation can be conducted on a block having a time difference greater than the prescribed value, i.e., a block subjected to a last write operation over the first prescribed period before.

Then, after the step S6, the controller 1002 creates a new time code corresponding to time data concerning time when write operation has been executed on the written block (at this point, the current time which is acquired) and time data concerning time when write operation has been executed on the selected block (at this point, the current time which is acquired) (step S7). And the controller 1002 stores the new time code in the time code area (time code block) 1d in association with the selected ordinary block (step S8).

On the other hand, if the controller 1002 judges at the step S5 that a block corresponding to the condition does not exist, then the processing proceeds to the step S7. And the controller 1002 creates a new time code corresponding to only time data concerning time when write operation has been executed on the written block (at this point, the current time which is acquired) in response to a command (step S7), and stores the new time code in the time code area (time code block) 1d in association with the selected ordinary block (step S8).

Note that the erase operation need not always be executed at the step S6.

Owing to the flow at the time of writing described heretofore, rewriting is conducted on the block before the data retention characteristics fall lower than a predetermined value. As a result, spread of threshold voltage distribution of the memory cell as already described is suppressed. In other words, data retention characteristics of the NAND flash memory 100 are improved.

FIG. 11 is a flow chart showing an example of a sequence at the read operation of the NAND flash memory 100 shown in FIG. 1.

As shown in FIG. 11, first, in response to a command or the like which is input from the controller 1002, the NAND flash memory 100 executes readout operation on a selected block of read object included in the ordinary memory cell area (block) is of the memory cell array 1 (step S11).

A subsequent flow ranging from step S2 to step S8 is the same as the flow ranging from the step S2 to the step S8 at the write operation shown in FIG. 10. In other words, the NAND flash memory 100 reads out data from a block of read object selected from ordinary blocks included in a plurality of blocks, and then reads out a time code from the time code block.

Owing to the flow at the time of reading, rewriting is conducted on the block which is read out, before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

An example in which the memory system 1000 periodically executes a sequence for improving data retention characteristics will now be described.

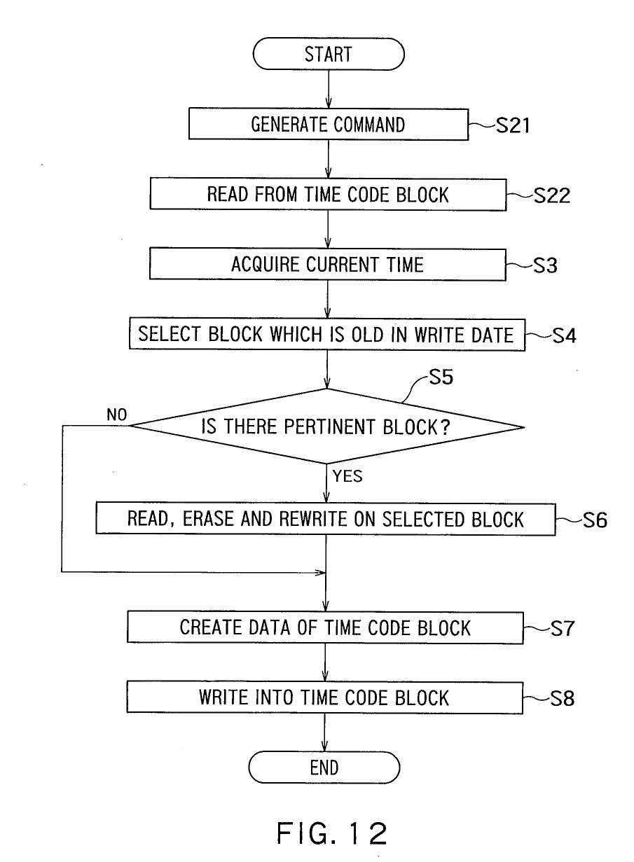

FIG. 12 is a flow chart showing an example of a periodic confirmation sequence of data retention characteristics in the NAND flash memory 100 shown in FIG. 1.

As shown in FIG. 12, first, the controller 1002 generates a confirmation command, for example, after elapse of a second prescribed period from the rewrite operation on the selected block shown in FIG. 11 and FIG. 12, and outputs the confirmation command to the NAND flash memory 100 (step S21). Note that the controller 1002 may generate the confirmation command after the second prescribed period has elapsed from turning on of the power supply, the ordinary read operation, write operation or erase operation.

Note that the controller 1002 acquires elapse of the second prescribed period from the count value which is output from the timer 1003. The controller 1002 judges the second prescribed period to have elapsed, for example, when the count value has increased from the count value at the rewrite operation by at least a prescribed value.

Then, in response to the conformation command which is input from the controller 1002, the NAND flash memory 100 reads out the time code of every block stored in the time code area (time code block) 1d (step S22). This time code includes time data concerning the time when the last write operation into a block corresponding to the time code was executed.

In other words, the NAND flash memory 100 reads out a time code from the time code block in response to a command which is input after a predetermined period has elapsed since a last write or read operation is conducted.

A subsequent flow ranging from step S3 to step S8 is the same as the flow ranging from the step S3 to the step S8 at the write operation shown in FIG. 10.

In other words, owing to the flow in the confirmation sequence, rewriting is conducted on a block, before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

According to the nonvolatile semiconductor storage device, data retention characteristics can be improved as described heretofore.

### Second Embodiment

In the first embodiment, an example of the configuration in which a dedicated block (the time code area 1d) which stores a time code is provided in the memory cell array 1 has been described.

Instead of setting a block as the time code storage area, the time code area may be assigned to a column of each word line to store the time code.

In the present second embodiment, therefore, an example of a configuration in which a time code is stored in each page of each block will now be described.

Except the configuration for storing a time code in each page instead of the block for storing a time code, configurations of the memory system 1000 and the NAND flash memory 100 are the same as those shown in the first embodiment.

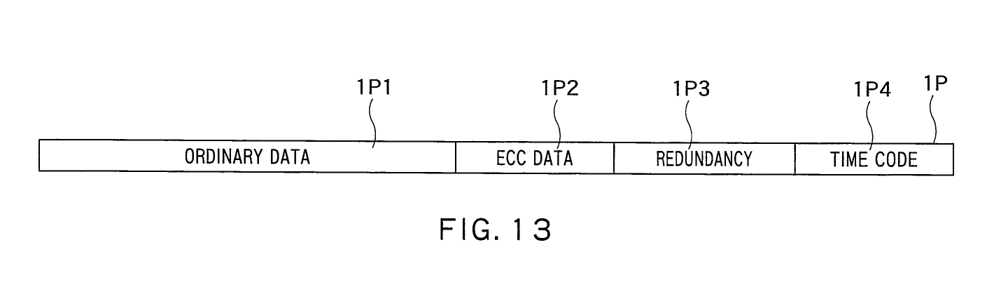

FIG. 13 is a diagram for explaining areas in one page of a block of the memory cell array 1 shown in FIG. 1.

As shown in FIG. 13, a page 1p includes an ordinary data area 1p1 for storing ordinary data, an ECC data area 1p2 for storing error checking correction (ECC) data, a redundancy area 1p3 for replacing a defective column, and a time code area 1p4 for storing a time code required for time management. Note that time data corresponding to time when a last write operation into a corresponding block has been executed is included in the time code. Note that the order of the ECC data area 1p2, the redundancy area 1p3, and the time code area 1p4 shown in FIG. 13 is an example, and the order may be different from that shown in FIG. 13.

Note that in the time code area 1p4, for example, the time code is stored by using a binary value or the time code is stored by using complementary data.

As a result, reliability of data stored in the time code area 1p4 is made high.

An example of operation for improving the data retention characteristics of the NAND flash memory 100 having the configuration described heretofore will now be described.

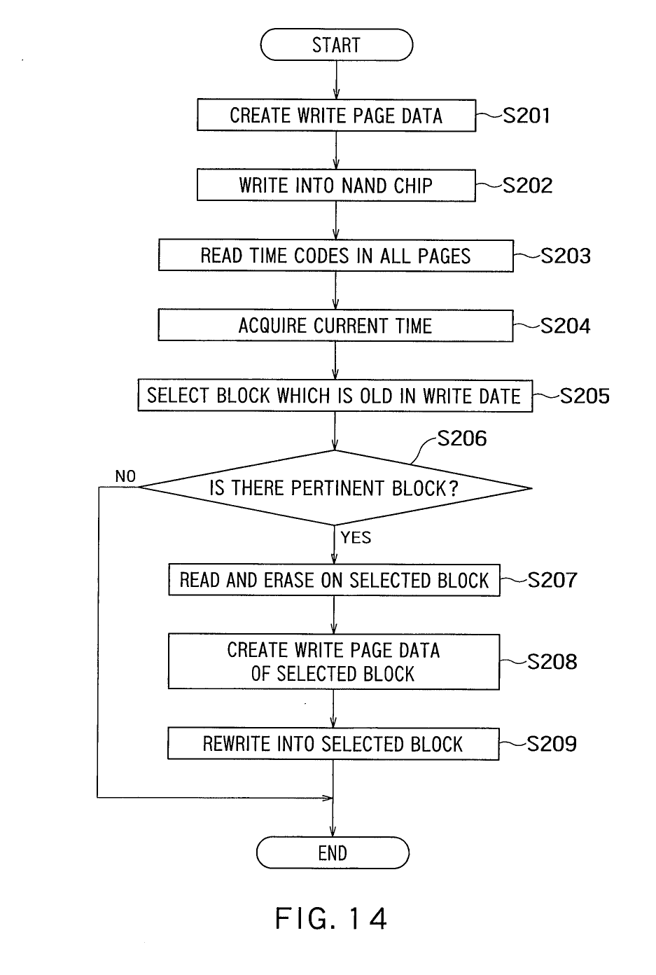

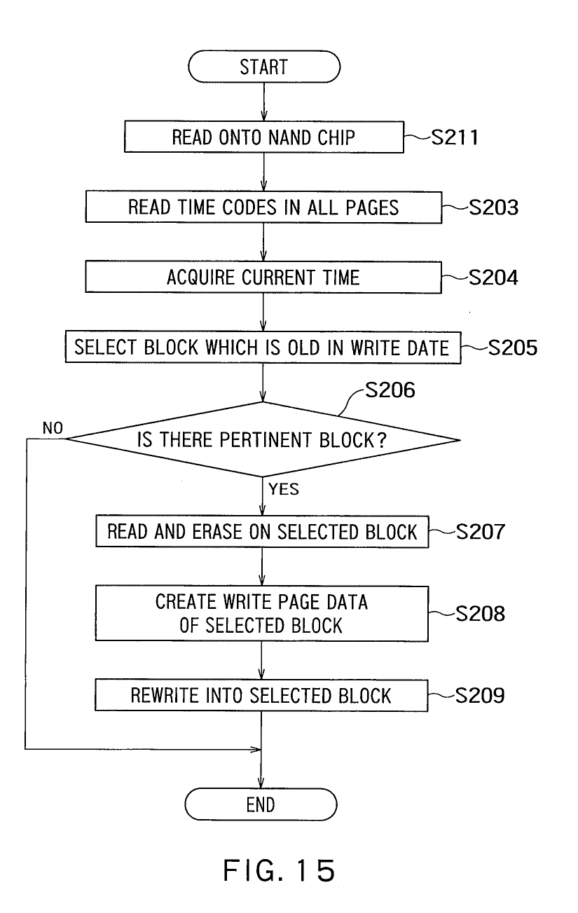

In the same way as the first embodiment, a sequence at the time of writing and a sequence at the time of reading are shown in FIG. 14 and FIG. 15, respectively.

FIG. 14 is a flow chart showing an example of a sequence at the write operation of the NAND flash memory 100 shown in FIG. 1.

As shown in FIG. 14, the controller 1002 first creates page data including ordinary write data, ECC data, and time code stored in each page shown in FIG. 13 (step S201).

Then, in response to a command or the like which is input from the controller 1002, the NAND flash memory 100 executes write operation of the created page data on the selected block of writing object (step S202).

Note that when the write operation is executed, data erasing of every selected block is executed before data writing. If the selected block has no data written therein, however, erasing is not executed.

Then, the NAND flash memory 100 reads out all time codes stored in the time code areas 1p4 of all pages 1p in each block (step S203). In this time code, time data concerning time when a last write operation has been executed in a block corresponding to the time code (including, for example, time when page data is created) is included.

In other words, the NAND flash memory 100 writes data into a block of a writing object selected from a plurality of blocks, and then reads out a time code from the time code block.

Then, the controller 1002 acquires current time on the basis of time information supplied from a time supply device such as the GPS module 1005 (step S204).

Then, the controller 1002 compares time in each time code which is read out with the current time, and selects a block having a time difference greater than a prescribed value (satisfying a prescribed condition). In other words, the controller 1002 selects blocks subjected to execution of a last write operation over a certain first prescribed period before, out of all blocks (step S205). Note that a restriction may be provided on the number of selected blocks.

Data corruption in the time code brings about a defect. Therefore, several bits in the time code stored in the time code area 1p4 may be handled as ECC bits.

If an error (data corruption in the time code) is detected on the basis of the ECC bits, then the time data is judged to have no reliability. Accordingly, the block having the detected error may also be made an object of selection. As a result, fail safety can be implemented by executing rewriting on the selected block.

Then, the processing proceeds to step S206. Upon judging that a block corresponding to the above-described condition exists, the controller 1002 executes a read operation and an erase operation on the selected block (step S207).

In other words, the NAND flash memory 100 reads data and erases the data on selected blocks for which a time difference between time in a time code which is read out and the current time becomes greater than a prescribed value.

And the controller 1002 creates page data to be rewritten into the selected block (step S208). Note that the page data to be rewritten into the selected block is ordinary data which is the same as the ordinary data stored in the selected block before rewriting, new ECC data, and a new time code corresponding to time data concerning time when write operation into the selected block has been executed (such as, for example, time when page data has been newly created).

Then, the controller 1002 executes write operation (rewrite operation) of the created new page data on the selected block (step S209).

In other words, the NAND flash memory 100 writes ordinary data which is the same as ordinary data read out and a new time code corresponding to time data concerning the current time into an ordinary data area and a time code area of a page in the selected block.

As a result, rewrite operation can be conducted on a block having a time difference greater than a prescribed value, i.e., a block subjected to a last write operation over the first prescribed period before. At this time, the new time code is stored in the time code area 1p4 of each page.

On the other hand, if the controller 1002 judges at the step S206 that there are no blocks corresponding to the condition, the controller 1002 finishes the flow.

Owing to the flow at the time of writing described heretofore, rewriting into the written block is conducted before data retention characteristics fall below a predetermined value. As a result, spread of threshold voltage distribution of the memory cell as already described is suppressed. In other words, data retention characteristics of the NAND flash memory 100 are improved.

Note that in the sequence in the second embodiment, it is necessary to access all pages in each block to read out the time code, unlike the sequence in the first embodiment.

FIG. 15 is a flow chart showing an example of a sequence at the read operation of the NAND flash memory 100 shown in FIG. 1.

As shown in FIG. 15, first, in response to a command or the like which is input from the controller 1002, the NAND flash memory 100 executes read operation onto a selected block of read object included in the ordinary memory cell area (block) 1a of the memory cell array 1 (step S211).

A subsequent flow ranging from step S203 to step S209 is the same as the flow ranging from the step S203 to the step S209 at the write operation shown in FIG. 14. In other words, the NAND flash memory 100 reads out data from a block of read object selected from a plurality of blocks, and then reads out a time code from the time code area.

Owing to the flow at the time of reading, rewriting is conducted on the block before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

An example in which the memory system 1000 periodically executes a sequence for improving data retention characteristics will now be described.

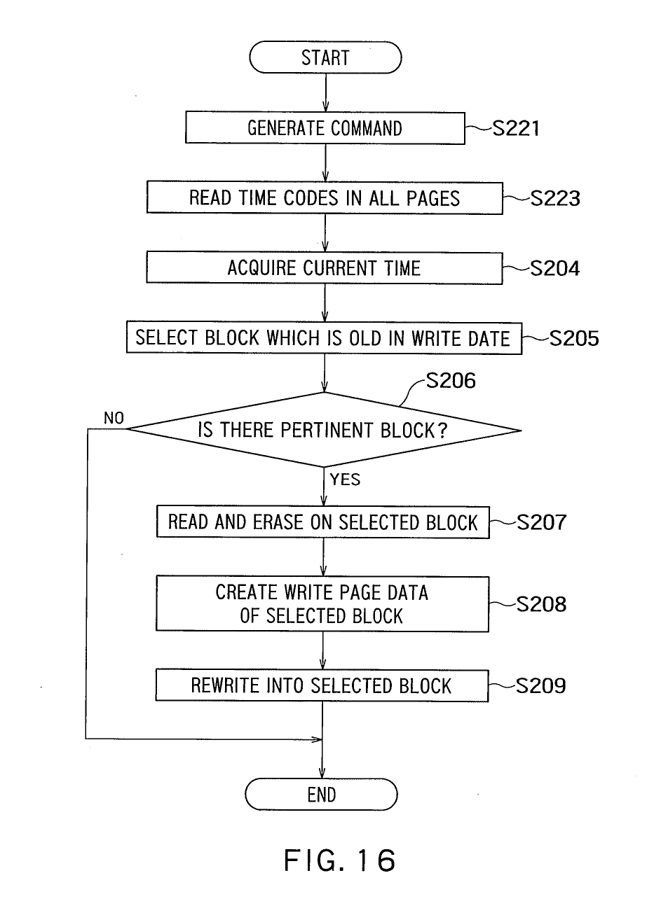

FIG. 16 is a flow chart showing an example of a periodic confirmation sequence of data retention characteristics in the NAND flash memory 100 shown in FIG. 1.

As shown in FIG. 16, first, the controller 1002 generates a confirmation command, for example, after elapse of a second prescribed period from the rewrite operation on the selected block shown in FIG. 14 and FIG. 15, and outputs the confirmation command to the NAND flash memory 100 (step S221). Note that the controller 1002 may generate the confirmation command after the second prescribed period has elapsed from turning on of the power supply, the ordinary read operation, write operation or erase operation.

Note that the controller 1002 acquires elapse of the second prescribed period from the count value which is output from the timer 1003. The controller 1002 judges the second prescribed period to have elapsed, for example, when the count value has increased from the count value at the rewrite operation by at least a prescribed value.

Then, in response to the conformation command which is input from the controller 1002, the NAND flash memory 100 reads out all time codes stored in the time code areas 1p4 of all pages 1p in each block (step S223). In this time code, time data concerning time when a last write operation has been executed in a block corresponding to the time code is included.

In other words, the NAND flash memory 100 reads out time codes from the time code areas in response to a command which is input after elapse of a predetermined period since execution of a last write or read operation.

A subsequent flow ranging from step S204 to step S209 is the same as the flow ranging from the step S204 to the step S209 at the write operation shown in FIG. 14.

In other words, owing to the flow in the confirmation sequence, rewriting is conducted on a block, before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

According to the nonvolatile semiconductor storage device in the present second embodiment, the data retention characteristics can be improved as described heretofore.

### Third Embodiment

In the second embodiment, an example of the configuration in which a time code of a certain block is stored in a page data area of each page in the block has been described.

Instead of providing a page data area in each page of each block, it is also possible to provide a time code page dedicated to time code in each block and store a time code corresponding to each block in the time code page in the block.

In the present third embodiment, therefore, an example of a configuration in which a time code is stored in a time code page in each block will now be described.

Except the configuration for storing a time code in a time code page in each block instead of the block for storing a time code, configurations of the memory system 1000 and the NAND flash memory 100 are the same as those shown in the first embodiment.

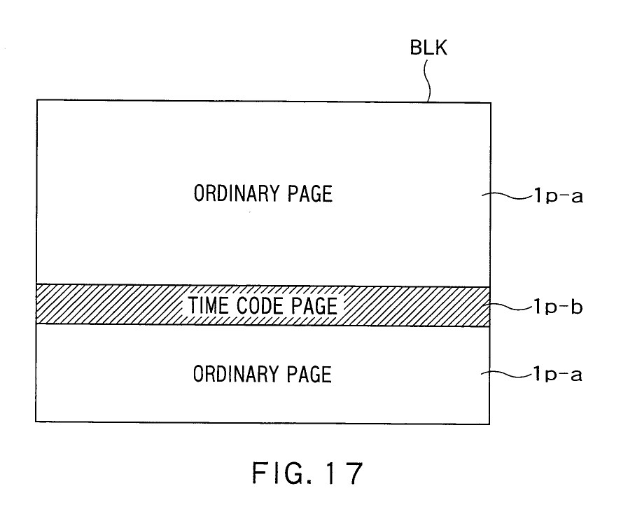

FIG. 17 is a diagram for explaining areas in one block of the memory cell array 1 shown in FIG. 1.

As shown in FIG. 17, a block BLK includes an ordinary page 1p-a for storing ordinary page data, and a time code page 1p-b for storing a time code which is necessary for time management of the block BLK. Note that time data corresponding to time when a last write operation into a corresponding block has been executed is included in the time code.

Note that in the time code page 1p-b, for example, the time code is stored by using a binary value or the time code is stored by using complementary data. Furthermore, the time code page 1p-b is assigned to, for example, a page near the center having high reliability in the block BLK.

An example of operation for improving the data retention characteristics of the NAND flash memory 100 having the configuration described heretofore will now be described.

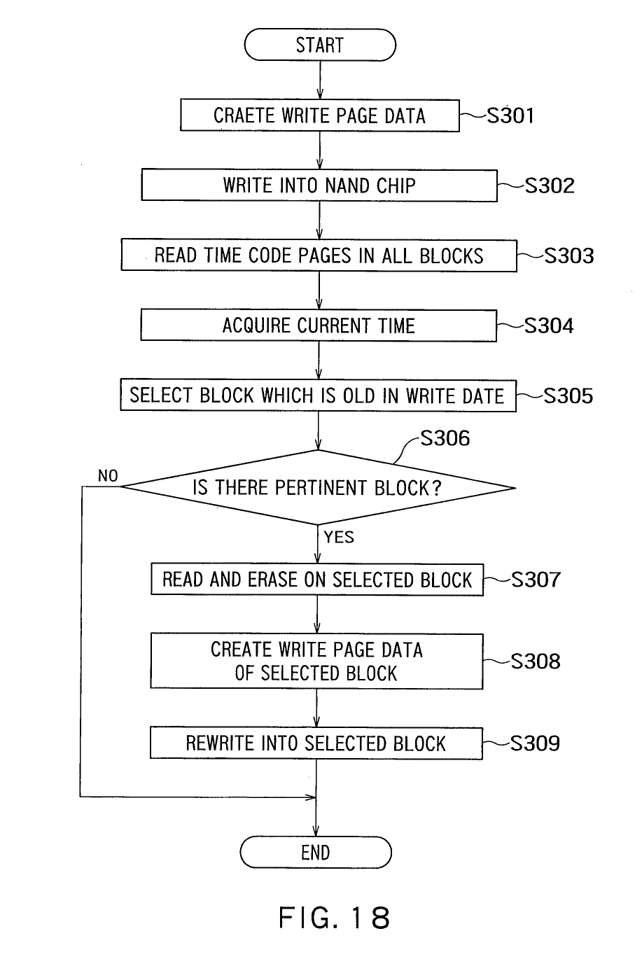

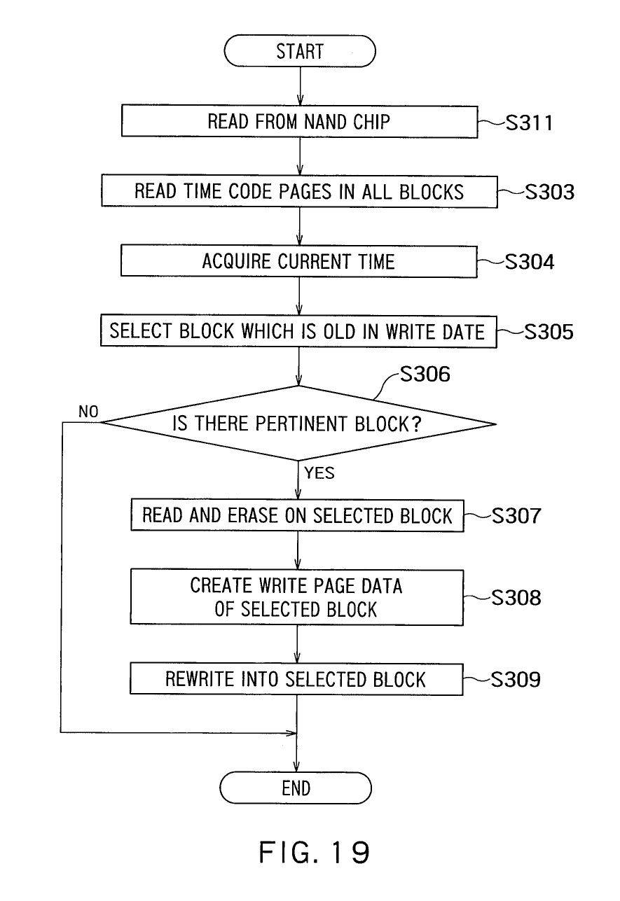

In the same way as the second embodiment, a sequence at the time of writing and a sequence at the time of reading are shown in FIG. 18 and FIG. 19, respectively.

FIG. 18 is a flow chart showing an example of a sequence at the write operation of the NAND flash memory 100 shown in FIG. 1.

As shown in FIG. 18, the controller 1002 first creates page data including ordinary write data to be stored in the ordinary page 1p-a shown in FIG. 17 and a new time code to be stored in the time code page 1p-b (step S301). In this time code, time data concerning time when write operation at this time has been executed in a block corresponding to the time code (including, for example, time when page data is created) is included.

Then, in response to a command or the like which is input from the controller 1002, the NAND flash memory 100 executes write operation of the created page data and time code into the ordinary page 1p-a and the time code page 1p-b in the selected block of write object (step S302).

Note that when the write operation is executed, data erasing of every selected block is executed before data writing. If the selected block has no data written therein, however, erasing is not executed.

Then, the NAND flash memory 100 reads out all time codes stored in the time code page 1p-b in each block (step S303). In this time code, time data concerning time when a last write operation has been executed in a block corresponding to the time code (including, for example, time when page data is created) is included.

In other words, the NAND flash memory 100 writes data into a block of a writing object selected from a plurality of blocks, and then reads out a time code from the time code area.

Then, the controller 1002 acquires current time on the basis of time information supplied from a time supply device such as the GPS module 1005 (step S304).

Then, the controller 1002 compares time in each time code which is read out with the current time, and selects a block having a time difference greater than a prescribed value (satisfying a prescribed condition). In other words, the controller 1002 selects blocks subjected to execution of a last write operation over a certain first prescribed period before, out of all blocks (step S305). Note that a restriction may be provided on the number of selected blocks.

Then, the processing proceeds to step S306. Upon judging that a block corresponding to the above-described condition exists, the controller 1002 executes a read operation and an erase operation on the selected block (step S307).

In other words, the NAND flash memory 100 reads data and erases the data on selected blocks for which a time difference between time in a time code which is read out and the current time becomes greater than a prescribed value.

And the controller 1002 creates page data (write data and a new time code) to be rewritten into the selected block (step S308).

Note that the page data (write data) to be rewritten into an ordinary page in the selected block is ordinary data which is the same as the ordinary data stored in the selected block before rewriting. Furthermore, page data (a time code) rewritten into a time code page in the selected block is a new time code corresponding to time data concerning time when write operation into the selected block has been executed (such as, for example, time when page data has been created newly).

Then, the controller 1002 executes write operation (rewrite operation) of the created new page data on the selected block (step S309).

In other words, the NAND flash memory 100 writes ordinary data which is the same as ordinary data read out and a new time code corresponding to time data concerning the current time into an ordinary page and a time code page in the selected block.

As a result, rewrite operation can be conducted on a block having a time difference greater than a prescribed value, i.e., a block subjected to a last write operation over the first prescribed period before. At this time, the new time code is stored in the time code page 1p-b.

On the other hand, if the controller 1002 judges at the step S306 that there are no blocks corresponding to the condition, the controller 1002 finishes the flow.

Owing to the flow at the time of writing described heretofore, rewriting into the written block is conducted before data retention characteristics fall below a predetermined value. As a result, spread of threshold voltage distribution of the memory cell as already described is suppressed. In other words, data retention characteristics of the NAND flash memory 100 are improved.

FIG. 19 is a flow chart showing an example of a sequence at the read operation of the NAND flash memory 100 shown in FIG. 1.

As shown in FIG. 19, first, in response to a command or the like which is input from the controller 1002, the NAND flash memory 100 executes read operation on a selected block of read object of the memory cell array 1 (step S311).

A subsequent flow ranging from step S303 to step S309 is the same as the flow ranging from the step S303 to the step S309 at the write operation shown in FIG. 18. In other words, the NAND flash memory 100 reads out data from a block of read object selected from a plurality of blocks, and then reads out a time code from the time code area.

Owing to the flow at the time of reading, rewriting is conducted on the block before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

An example in which the memory system 1000 periodically executes a sequence for improving data retention characteristics will now be described.

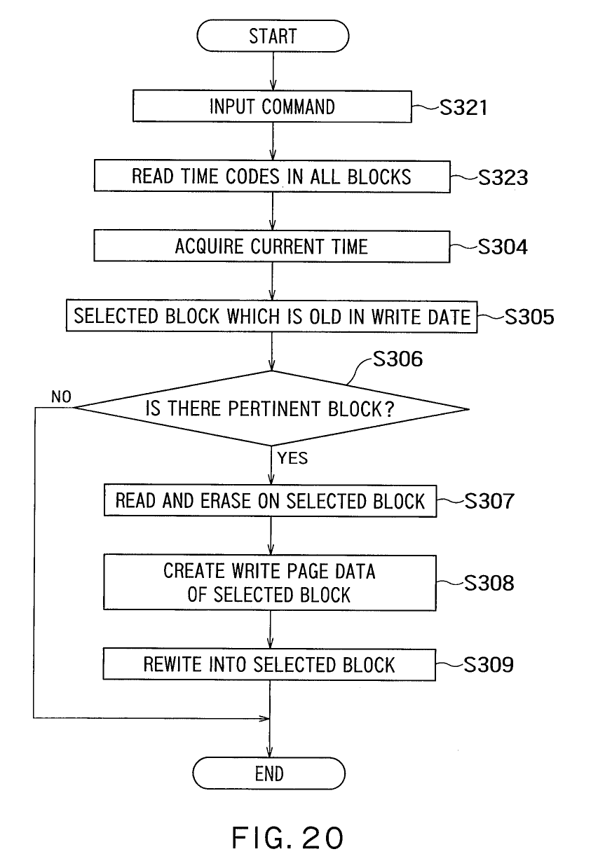

FIG. 20 is a flow chart showing an example of a periodic confirmation sequence of data retention characteristics in the NAND flash memory 100 shown in FIG. 1.

As shown in FIG. 20, first, the controller 1002 generates a confirmation command, for example, after elapse of a second prescribed period from the rewrite operation on the selected block shown in FIG. 18 and FIG. 19, and outputs the confirmation command to the NAND flash memory 100 (step S321). Note that the controller 1002 may generate the confirmation command after the second prescribed period has elapsed from turning on of the power supply, the ordinary read operation, write operation or erase operation.

Note that the controller 1002 acquires elapse of the second prescribed period from the count value which is output from the timer 1003. The controller 1002 judges the second prescribed period to have elapsed, for example, when the count value has increased from the count value at the rewrite operation by at least a prescribed value.

Then, in response to the conformation command which is input from the controller 1002, the NAND flash memory 100 reads out all time codes stored in the time code page 1p-b in each block (step S323). In this time code, time data concerning time when a last write operation has been executed in a block corresponding to the time code is included.

In other words, the NAND flash memory 100 reads out time codes from the time code areas in response to a command which is input after elapse of a predetermined period since execution of a last write or read operation.

A subsequent flow ranging from step S304 to step S309 is the same as the flow ranging from the step S304 to the step S309 at the write operation shown in FIG. 14.

In other words, owing to the flow in the confirmation sequence, rewriting is conducted on a block, before the data retention characteristics fall below a predetermined value, in the same way as the flow at the time of writing. As a result, spread of threshold voltage distribution of the memory cell as already described is suppressed. In other words, data retention characteristics of the NAND flash memory 100 are improved.

According to the nonvolatile semiconductor storage device in the present third embodiment, the data retention characteristics can be improved as described heretofore, in the same way as the first and second embodiments.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising a memory cell array which comprises a plurality of blocks each comprising a plurality of memory cells,
ordinary data being stored in ordinary blocks included in the plurality of blocks,
a time code corresponding to time when a last write operation into the ordinary block is executed being stored in a time code block included in the plurality of blocks,
wherein
the time code is read out from the time code block,
current time is acquired,
with respect to selected one of the ordinary blocks for which a time difference between time in the time code read out and the current time becomes greater than a prescribed value, data is read and erased and the data read out is written, and
a new time code corresponding to the current time is written into the time code block in association with the selected ordinary block.

2. The nonvolatile semiconductor storage device according to claim 1, wherein after data is written into a block of write object selected from the ordinary blocks included in the plurality of blocks, the time code is read from the time code block.

3. The nonvolatile semiconductor storage device according to claim 1, wherein after data is read from a block of read object selected from the ordinary blocks included in the plurality of blocks, the time code is read from the time code block.

4. The nonvolatile semiconductor storage device according to claim 1, wherein in response to a command which is input after elapse of a predetermined period since a last write or read operation, the time code is read from the time code block.

5. The nonvolatile semiconductor storage device according to claim 1, wherein the nonvolatile semiconductor storage device is a NAND flash memory.

6. The nonvolatile semiconductor storage device according to claim 1, wherein the nonvolatile semiconductor storage device is a MONOS memory.

7. The nonvolatile semiconductor storage device according to claim 1, wherein the nonvolatile semiconductor storage device is a ReRAM memory.

8. A nonvolatile semiconductor storage device comprising a memory cell array which comprises a plurality of blocks each comprising a plurality of memory cells,
ordinary data being stored in ordinary data areas in a page consisting of memory cells connected to a word line of the block,
a time code corresponding to time when a last write operation into the block is executed being stored in a time code area in the page,
wherein
the time code is read out from the time code area,
current time is acquired,
with respect to selected one of the blocks for which a time difference between time in the time code read out and the current time becomes greater than a prescribed value, data is read and erased, and
ordinary data being the same as the ordinary data is written into the ordinary data area in the page of the selected block and a new time code corresponding to the current time is written into the time code area in the page of the selected block.

9. The nonvolatile semiconductor storage device according to claim 8, wherein after data is written into a block of write object selected from the plurality of blocks, the time code is read from the time code area.

10. The nonvolatile semiconductor storage device according to claim 8, wherein after data is read from a block of read object selected from the plurality of blocks, the time code is read from the time code area.

11. The nonvolatile semiconductor storage device according to claim 8, wherein in response to a command which is input after elapse of a predetermined period since a last write or read operation, the time code is read from the time code area.

12. The nonvolatile semiconductor storage device according to claim 8, wherein the nonvolatile semiconductor storage device is a NAND flash memory.

13. The nonvolatile semiconductor storage device according to claim 8, wherein the nonvolatile semiconductor storage device is a MONOS memory.

14. The nonvolatile semiconductor storage device according to claim 8, wherein the nonvolatile semiconductor storage device is a ReRAM memory.

15. A nonvolatile semiconductor storage device comprising a memory cell array which comprises a plurality of blocks each comprising a plurality of memory cells,
ordinary data being stored in ordinary page included in a plurality of pages consisting of memory cells connected to word lines of the block,
a time code corresponding to time when a last write operation into the block is executed being stored in a time code page included in the plurality of pages,
wherein
the time code is read out from the time code page,
current time is acquired,
with respect to selected one of the blocks for which a time difference between time in the time code read out and the current time becomes greater than a prescribed value, data is read and erased, and
ordinary data being the same as the ordinary data is written into the ordinary data page, in the page of the selected block and a new time code corresponding to the current time is written into the time code page, in the page of the selected block.

16. The nonvolatile semiconductor storage device according to claim 15, wherein after data is written into a block of write object selected from the plurality of blocks, the time code is read from the time code page.

17. The nonvolatile semiconductor storage device according to claim 15, wherein after data is read from a block of read object selected from the plurality of blocks, the time code is read from the time code page.

18. The nonvolatile semiconductor storage device according to claim 15, wherein in response to a command which is input after elapse of a predetermined period since a last write or read operation, the time code is read from the time code page.

19. The nonvolatile semiconductor storage device according to claim 15, wherein the nonvolatile semiconductor storage device is a NAND flash memory.

20. The nonvolatile semiconductor storage device according to claim 15, wherein the nonvolatile semiconductor storage device is a MONOS memory.
